(19) United States
(12) Patent Application Publication
(10) Pub. No.: US 2019/0312085 A1
(43) Pub. Date: Oct. 10, 2019

(54) LIGHTING AND/OR SIGNALLING DEVICE FOR A MOTOR VEHICLE

(71) Applicant: VALEO VISION, Bobigny Cedex (FR)

(72) Inventors: Gilles LE-CALVEZ, Bobigny Cedex (FR); Pierre ALBOU, Bobigny Cedex (FR)

(73) Assignee: VALEO VISION, Bobigny Cedex (FR)

(21) Appl. No.: 16/314,806

(22) PCT Filed: Jul. 4, 2017
(86) PCT No.: PCT/EP2017/066639

§ 371 Date: Jan. 2, 2019

(30) Foreign Application Priority Data
Jul. 5, 2016 (FR) 1656447

(51) Int. Cl. H01L 27/15; F21S 41/143; F21S 41/255; F21S 43/14; H01L 23/525

(52) U.S. Cl. CPC H01L 27/156; F21S 41/143; H01L 23/5252; F21S 43/14; H01L 23/5256; F21S 41/255

(57) ABSTRACT

A semiconductor light source includes at least one substrate and a plurality of submillimetre-sized light-emitting rods that extend from a first face of the substrate. The light-emitting rods are arranged in a plurality of groups the selective activation of which allows a plurality of light beams to be produced. At least two groups of rods are electrically connected to one another by an irreversibly modifiable conductive bridge such that the irreversible modification of this conductive bridge irreversibly modifies the electrical dependence of the two groups on one another.

The invention concerns the field of lighting and/or signaling, in particular for motor vehicles. It relates more particularly to a light source and a lighting device for lighting and/or signaling in a motor vehicle, which comprises a light source of this kind and an optic for shaping light rays emitted by this source.

Motor vehicles are fitted with various headlights producing light beams that are dedicated to specific lighting and/or signaling functions. Such headlights conventionally comprise a housing containing one or more optical modules producing light beams that are projected out of the housing.

An optical module for a motor vehicle headlight generally comprises at least one light source and optical members, such as reflectors and/or light guides, directing the light produced by the one or more light sources towards a transparent wall through which the light beams produced by the optical module are projected. The one or more light sources can be activated selectively by control means according to the lighting and/or signaling requirements of the vehicle. The one or more light sources and the associated optical system are configured to perform lighting and/or signaling functions for the vehicle, which are for the most part regulated. In the context of the present invention, the low beam and high beam lighting functions, the stop light function, the marker light function and the daytime running light function are more specifically, but not exclusively, to be considered.

The “low beam” mode provides a more limited lighting of the road, but nonetheless offers good visibility without dazzling other road users, whereas the “high beam” mode allows the road far in front of the vehicle to be brightly lit.

Regarding the marker light function, a motor vehicle is fitted with headlights producing marker light beams both at the rear and at the front. The colour of the light beams projected by the marker lights is predefined in accordance with regulations, and the light source consequently produces a light of a given colour, namely substantially red at the rear and white at the front.

Regarding the daytime running light function, a motor vehicle is fitted with headlights at the front acting as daytime running lights (DRLs). The daytime running light function is used to draw attention to the vehicle in lighting conditions that are equivalent to broad daylight. A daytime running light is activated by an automatic control means, such that the daytime running light is turned on continuously as soon as the high beam or low beam lights of the vehicle are turned off. Furthermore, the daytime running lights must be turned off when the turn indicator lights are turned on, so as to make the turn indicator lights more visible. The colour of the light beams projected by the daytime running lights is predefined in accordance with regulations, and the light source consequently produces a light of a given colour, namely white in particular.

In this context, it made sense to incorporate various lighting and/or signaling functions such as those described above within one and the same headlight. Specifically, such arrangements allow the aesthetics of the vehicle to be enhanced by limiting the bulk of the front face of the vehicle caused by a plurality of headlights assigned to respective specific lighting and/or signaling functions.

It should be noted that a vehicle may be produced in several ranges and that an entry-level vehicle may have a smaller number of lighting and/or signaling functions in one and the same headlight in comparison with respect to a top-of-the-range vehicle. This variety offered to the user entails substantial manufacturing costs for the motor vehicle manufacturer and for the equipment manufacturer responsible for designing lighting and/or signaling headlights, since various types of headlights must be provided.

The light sources are increasingly commonly made up of light-emitting diodes, in particular to afford advantages in terms of bulk and of autonomy in comparison with conventional light sources. The use of light-emitting diodes in lighting modules has furthermore enabled market players (motor vehicle manufacturers and lighting device designers) to add a creative touch when designing these devices, in particular through the use of an ever-increasing number of these light-emitting diodes to produce optical effects. However, the application thereof in the context described above does not make it possible to create, for the outside observer, a visual effect in which the various functions are performed by one and the same light source, since it would be necessary to provide a light-emitting diode for each of the lighting functions, and since these various diodes are spaced apart from one another. The separation between the two emitters is non-negligible, the separation potentially representing, for example, between 8 and 12% of the size of the chip, which results in an angular separation between the beams produced by the same headlight. It would then require the use of optics providing a high degree of mixing, for example elliptical collectors and/or light guides, i.e. optics that substantially modify the light rays emitted by the light sources in order to mix them, such that the luminous area produced by each of the zones is perceived as being continuous.

The invention aims to provide an alternative using light-emitting diodes, such as will be presented below. In this context, a subject of the invention is a semiconductor light source comprising at least one substrate and a plurality of submillimetre-sized light-emitting rods that extend from a first face of the substrate, said light-emitting rods being arranged in a plurality of groups the selective activation of which allows a plurality of light beams to be produced. At least two groups of rods are electrically connected to one another by an irreversibly modifiable conductive bridge such that the irreversible modification of this conductive bridge irreversibly modifies the electrical dependence of the two groups on one another.

In other words, a conductive bridge is arranged between two selectively activatable groups with an initial state allowing or preventing these two groups to be or from being electrically connected. When the electrical connection is allowed, i.e. when the conductive bridges in an active state, the two groups are no longer selectively activatable, i.e. activating one results in the activation of the other. Conversely, when the conductive bridge is in a passive state, no electrical connection between the two groups is allowed and they can now be selectively activated, independently of one another. The conductive bridge is noteworthy in that it can change state once in order to switch either from its original active state to a passive state in which it participates in making the groups of rods independent and hence in producing a complex light beam, or from its original passive state to an active state in which it participates in grouping the rods together into a simultaneously activatable set.

According to one feature of the invention, in which the light-emitting rods are distributed in a plurality of groups of rods that are arranged in series and the selective activation of which allows a plurality of light beams to be produced, provision may be made for said groups of rods to be connected pairwise by an irreversibly modifiable conductive bridge.

Provision may also be made for at least one group of rods to be able to be connected to a plurality of groups of rods or to each of the groups of this plurality via an irreversibly modifiable conductive bridge.

According to one particular arrangement of the light source according to the invention, a plurality of groups of rods that are arranged on one side of a boundary line are connected to one another by irreversibly modifiable conductive bridges, while a set of rods that is distinct from and independent of said groups of rods is arranged on the other side of the boundary line.

It is thus possible to impose the presence of two selectively activatable groups regardless of how the light source is used, in particular, in the context of a motor vehicle lighting application, for performing low beam and high beam functions.

According to a first embodiment, the one or more irreversibly modifiable conductive bridges consist of fuse devices that are configured to blow beyond a threshold current value. Below this threshold value, the fuses act as conductors between the groups of rods that they connect, such that controlling the power supply of the rods of a first group allows a second group that is connected via this fuse to be supplied with power, while above this threshold value, the fuses blow, such that the first and second groups of rods are electrically isolated and can be activated only selectively.

At least one fuse device may consist of a zinc and/or gold wire. This wire may for example have a diameter of about 30 micrometres. A simple initial connection of wire-bonding type is thus made, it being understood that wire bonding consists of wiring by means of a wire, or bridge, soldered between two connection pads provided for this purpose, here for each of the groups of rods to be connected. A sufficiently large current, by way of example 1 A for the given wire diameter of 30 micrometres, is then applied, which current is large enough to burn out the wire.

According to a second embodiment, the one or more irreversibly modifiable conductive bridges may consist of antifuse devices that are configured to take effect beyond a threshold voltage value. Below this threshold value, the antifuses participate in isolating the groups of rods between which they are arranged, such that the corresponding first and second groups of rods can be activated selectively, while above this threshold value, the antifuses burn out such that the semiconductor becomes definitively conductive and electrically unites the first and second groups of rods.

Whichever embodiment is chosen to obtain these irreversibly modifiable conductive bridges, they may be produced on either of the faces of the substrate. In the case in which the conductive bridges are produced on the first face of the substrate, from which the light-emitting rods project, the face of the substrate opposite this first face may bear a printed circuit board.

Provision may be made for the semiconductor light source comprising a plurality of submillimetre-sized light-emitting rods to further include a layer of polymer material in which the rods are at least partially embedded; this polymer material may be silicone based, it being understood that the polymer material is silicone based as long as it consists primarily of silicone, for example at least 50% and in practice around 99%. The layer of polymer material may comprise a luminophore or a plurality of luminophores that are excited by the light generated by at least one of the plurality of rods. A luminophore, or light converter, and for example a phosphor, is understood to mean the presence of at least one luminescent material designed to absorb at least a portion of at least one excitation light emitted by a light source and to convert at least a portion of said absorbed excitation light into a light emission having a wavelength that is different from that of the excitation light. This phosphor, or this plurality of phosphors, may be at least partially embedded in the polymer, or else arranged on the surface of the layer of polymer material. In the case in which the one or more irreversibly modifiable conductive bridges are arranged on the upper face of the substrate, i.e. the face from which the light-emitting rods project, the layer of polymer material also participates in embedding these conductive bridges, it being understood that they are placed in their final state, after being modified or otherwise, before being covered with the layer of polymer material.

All of the light-emitting rods may extend from one and the same substrate, and these rods may in particular be formed directly on this substrate. Provision may be made for the substrate to be silicon based or silicon carbide based. It is understood that the substrate is silicon-based as long as it consists primarily of silicon, for example to at least 50%, and in practice to around 99%.

According to features that are specific to the formation of the light-emitting rods and to the arrangement of these light-emitting rods on the substrate, it may be provided that, with each feature being able to be taken alone or in combination with the others:
each rod has a cylindrical general shape, in particular with a polygonal cross section; it may be provided that each rod has the same general shape, and in particular a hexagonal shape;
the rods are each delineated by an end face and by a circumferential wall that extends along a longitudinal axis of the rod defining its height, the light being emitted at least from the circumferential wall; this light could also be emitted via the end face;
each rod may have an end face that is substantially perpendicular to the circumferential wall, and, in various variants, it may be provided that this end face is substantially planar or curved or pointed at its center;
the rods are arranged in a two-dimensional array, whether this array be regular, with a constant spacing between two successive rods of a given alignment, or whether the rods be arranged in quincunx; it is understood that in this scenario of a two-dimensional array, the rods are considered to be arranged in rows;
the height of a rod is between 1 and 10 micrometres;
the largest dimension of the end face is smaller than 2 micrometres;
the distance separating two immediately adjacent rods is equal to 2 micrometres at least and equal to 100 micrometres at most.

As mentioned above, the invention further relates to a lighting and/or signaling device comprising a light source such as described above, as well as an optic for shaping the rays emitted by the light source for emitting a light beam out of the device.

Shaping optic is understood to mean means that make it possible to change the direction of at least a portion of the light rays. This shaping optic may consist of one or more reflectors, or else of one or more lenses and/or microlenses, potentially arranged in an array, or else of a combination of these two options. The shaping optic could be arranged so as to have a source focal point that is not centred on the light source. This makes it possible, in particular, to emit an image that appears continuous, using direct imaging, without having to provide a system that has to modify the source image before being emitted.

Thus, a technology is applied to the motor vehicle sector that consists in producing the light-emitting zone using a plurality of light-emitting rods that are grown on a substrate, so as to produce a three-dimensional topology. It is understood that this three-dimensional topology has the advantage of multiplying the light-emitting surface with respect to the light-emitting diodes known hitherto in the motor vehicle sector, namely substantially planar diodes. It is therefore possible to provide a very luminous white light at a reduced cost price.

The light source may include a plurality of rods that are electrically connected so as to form selectively addressable groups, each of said groups being configured to form a pixel of said light beam, the number and the shape of said pixels potentially changing after the one or more conductive bridges have been irreversibly modified.

The device is thus used both in a front headlight and in a tail light of a motor vehicle.

The invention also relates to a process for manufacturing a light source such as presented above, in which various layers are stacked to form the substrate on which the light-emitting rods are grown, at least one end layer of the stack consisting of an interconnect mask for electrically interconnecting the rods including one or more reversibly modifiable conductive bridges, and in which, prior to the operation of connecting a printed circuit board to a lower face of the substrate facing away from the light-emitting rods, a suitable connector is applied to the interconnect mask so as to match at least one of said conductive bridges of the mask with a conductive element of the connector.

Other features and advantages of the present invention will become more clearly apparent in light of the description and the drawings, among which:

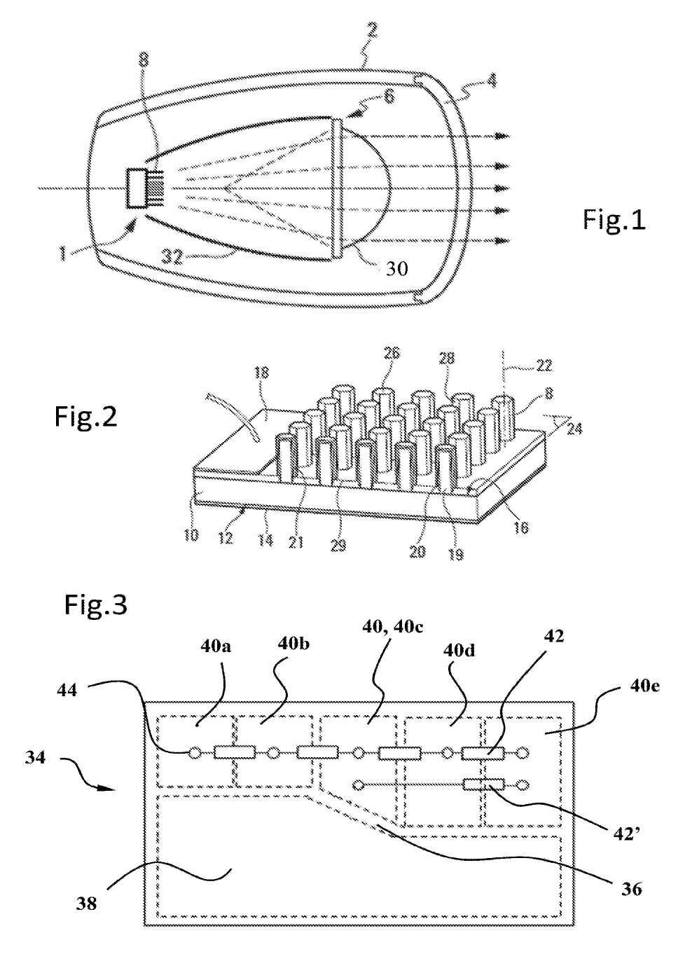

FIG. 1 is a cross-sectional view of a lighting and/or signaling device according to the invention, illustrating light rays emitted by a semiconductor light source according to the invention in the direction of a shaping optic;

FIG. 2 is a schematic, perspective depiction of the semiconductor light source of FIG. 1, including a plurality of rods projecting from a substrate, in which a row of light-emitting rods may be seen in cross section; and

FIG. 3 is a view from below of a light source according to one embodiment of the invention, in which irreversibly modifiable conductive bridges are arranged between groups of rods on a lower face of the substrate.

A lighting and/or signaling device for a motor vehicle includes a light source 1, in particular contained in a housing 2, which is closed by an outer lens 4 and defines an internal volume for accepting this emitting device. The light source is associated with an optic 6 for shaping a portion at least a portion of the light rays emitted by the semiconductor source. As could be explained above, the shaping optic changes a direction of at least a portion of the light rays emitted by the source.

The light source 1 is a semiconductor source comprising submillimetre-sized light-emitting rods, that is to say three-dimensional semiconductor sources, as will be explained below, in contrast to conventional two-dimensional sources that can be equated to substantially planar sources on account of their thickness, of the order of a few nanometres, while a light-emitting rod source has a height equal to one micrometre at most.

The light source 1 comprises a plurality of submillimetre-sized light-emitting rods 8, which will hereinafter be termed light-emitting rods. These light-emitting rods 8 originate on one and the same substrate 10. Each light-emitting rod extends perpendicularly, or substantially perpendicularly, projecting from the substrate, in this case produced from silicon, with other materials, such as silicon carbide, being able to be used without departing from the context of the invention. In the case illustrated, the rods are grown using gallium nitride (GaN), but it will be understood that other materials could be used without departing from the context of the invention, and in particular the light-emitting rods could be made from an alloy of aluminium and gallium nitride (AlGaN), or from an alloy of aluminium, indium and gallium nitride (AlInGaN).

In FIG. 2, the substrate 10 has a lower face 12, to which a first electrode 14 is applied, and an upper face 16, from which the light-emitting rods 8 project and to which a second electrode 18 is applied. Various layers of material are superposed on either side of the substrate, in particular after the light-emitting rods have grown from the substrate, achieved in this case by a bottom-up approach. Among these various layers may be found an interconnect mask, formed of at least one layer of electrically conductive material, so as to allow the rods to be supplied with electrical power. This layer is etched in such a way as to connect the rods to one another, it then being possible to simultaneously control the turning-on of these rods by means of a control module (not shown here). Provision may be made for at least two light-emitting rods or at least two groups of light-emitting rods of the semiconductor light source 1 to be arranged so as to be turned on separately by means of a turn-on control system.

The submillimetre-sized light-emitting rods extend from the substrate and each include, as may be seen in FIG. 4, a core 19 made of gallium nitride, arranged around which are quantum wells 20 formed by a radial stacking of layers of different materials, in this case gallium nitride and gallium-indium nitride, and a shell 21, also made of gallium nitride, surrounding the quantum wells.

Each rod extends along a longitudinal axis 22 defining its height, the base 23 of each rod being arranged in a plane 24 of the upper face 16 of the substrate 10.

The light-emitting rods 8 of the semiconductor light source advantageously have the same shape. These rods are each delineated by an end face 26 and by a circumferential wall 28 that extends along the longitudinal axis. When the light-emitting rods are doped and subjected to polarization, the resulting light at the output of the semiconductor source is emitted mainly from the circumferential wall 28, it being understood that it may be provided that at least a small amount of light rays also exit from the end face 26. The result of this is that each rod acts as a single light-emitting diode, and that the density of the light-emitting diodes 8 improves the light output of this semiconductor source.

The circumferential wall 28 of a rod 8, corresponding to the gallium nitride shell, is covered with a layer of transparent conductive oxide (TCO) 29 that forms the anode of each rod, complementary to the cathode formed by the substrate. This circumferential wall 28 extends along the longitudinal axis 22 from the substrate 10 as far as the end face 26, the distance from the end face 26 to the upper face 16 of the substrate, from which the light-emitting rods 8 originate, defining the height of each rod. By way of example, provision is made for the height of a light-emitting rod 8 to be between 1 and 10 micrometres, whereas provision is made for the largest transverse dimension of the end face, perpendicular to the longitudinal axis 22 of the light-emitting rod in question, to be less than 2 micrometres. Provision may also be made for defining the surface area of a rod, in a cross-sectional plane perpendicular to this longitudinal axis 22, to be within a range of defined values, and in particular between 1.96 and 4 square micrometres.

These dimensions, which are given by way of nonlimiting example, make it possible in particular to differentiate a semiconductor light source comprising light-emitting rods from a light source with substantially planar diode sources, as used previously.

It is understood that, when forming the rods 8, the height may be modified from one light source to another in such a way as to boost the luminance of the semiconductor light source when the height is increased. The height of the rods may also be modified within a single light source, such that the height, or heights, of a group of rods may differ from that, or those, of another group of rods, these two groups forming the semiconductor light source comprising submillimetre-sized light-emitting rods.

The shape of the light-emitting rods 8 may also vary from one device to another, in particular in terms of the cross section of the rods and in terms of the shape of the end face 26. FIG. 2 illustrates light-emitting rods taking the general shape of a cylinder, and in particular with a polygonal cross section, more particularly a hexagonal cross section in this case. It is understood that it is important, in order for light to be able to be emitted through the circumferential wall, that the latter have a polygonal or circular shape, for example.

Moreover, the end face 26 may take a shape that is substantially planar and perpendicular to the circumferential wall, such that it extends substantially parallel to the upper face 16 of the substrate 10, as illustrated in FIG. 2, or else it may take a curved or pointed shape at its centre, so as to multiply the directions in which the light exiting this end face is emitted.

The light-emitting rods 8 are arranged in a two-dimensional array in FIG. 2. This arrangement could be such that the light-emitting rods are arranged in quincunx. The invention covers other distributions of the rods, in particular having rod densities that may vary from one light source to another, and that may vary in different zones of one and the same light source. The number of light-emitting rods 8 projecting from the substrate 10 may vary from one device to another, in particular so as to increase the luminous density of the light source, but it is recognized that a separating distance, i.e. a distance measured between two longitudinal axes of adjacent light-emitting rods, must be equal to 2 micrometres at least, in order for the light emitted by the circumferential wall 28 of each light-emitting rod 8 to be able to exit the array of rods. Moreover, provision is made for these separating distances to be no greater than 100 micrometres.

The light source 1 may furthermore include a layer (not shown here) of a polymer material in which light-emitting rods 8 are at least partially embedded. The layer of polymer material may thus extend over the entire extent of the substrate or only around a determined group of light-emitting rods, protecting the light-emitting rods 8 without interfering with the diffusion of the light rays. Furthermore, it is possible to integrate, into this layer of polymer material, wavelength conversion means, for example luminophores, that are able to absorb at least a portion of the rays emitted by one of the rods and to convert at least a portion of said absorbed excitation light into a light emission having a wavelength that is different from that of the excitation light. Provision may indiscriminately be made for the wavelength conversion means to be embedded in the bulk of the polymer material, or else that they are arranged on the surface of the layer of this polymer material.

The light source 1 in this case takes a rectangular shape, but it will be understood that it may take other general shapes, in particular a parallelogram shape, without departing from the context of the invention.

In the lighting and/or signaling device according to the invention, such as illustrated in FIG. 3, the shaping optic 6 consists of a lens 30 that deflects the rays emitted by the light source that is arranged at the object focal point of the lens so as to form a regulatory infinite beam, that is to say a beam that complies with the photometry chart of any lighting and/or signaling beam. A collector 32 may be is provided between the light source 1 and the lens 30 in order to deflect the rays in the direction of the lens, it being understood that the three-dimensional form of the semiconductor light source according to the invention generates light ray emissions in various directions.

The means implemented in the invention to make it possible to produce, with a light source of standard manufacture, a plurality of different light sources that are specifically for performing one or more determined lighting and/or signaling functions.

FIG. 3 illustrates an example of an interconnect mask allowing a plurality of groups of rods, distributed on either side of a boundary line 36, to be selectively controlled in the following manner: a first group 38 of light emitting rods for performing a low beam function and a second group 40 of rods for performing a lighting function that is complimentary to the low beam function in order to form a high beam, this second group being arranged in a plurality of subgroups, here numbering five, that are arranged in series along the boundary line 36.

The boundary line may be obtained through the physical implementation of a wall projecting from the substrate, but it is primarily achieved by the given wiring of any light-emitting rod 8 to any another.

The first group 38 and the second group 40 of rods, arranged on either side of the boundary line 36, are defined in particular by a distinct electrical connection, which allows the first group of rods to be controlled selectively with respect to the second group of rods, and the subgroups of rods of the second group may be selectively activatable with respect to one another, i.e. rods of the second group may be controlled independently of other rods of the second group.

Irreversibly modifiable conductive bridges 42 have been arranged between some of the subgroups of rods of the second group, which conductive bridges allow two subgroups to be electrically connected to one another, respectively, each conductive bridge extending between two electrical contact points 44 that are arranged on either side of the subgroups, respectively. In the standard state of the light-emitting rod light source, a plurality of groups or subgroups of rods is formed, and at least one conductor bridge is arranged between two of these groups or subgroups so as to make it possible to modify the electrical connection between them with respect to the standard state of the light source, i.e. so as to make it possible to make the groups or subgroups electrically dependent when they are originally electrically isolated due to the presence of an antifuse, or else conversely so as to make it possible to make the groups or subgroups electrically independent when they are originally electrically connected due to the presence of a fuse. The change of state of a conductive bridge irreversibly modifies the electrical dependence of the two groups connected by this bridge with respect to one another.

FIG. 3 illustrates both conductive bridges 42 that connect two successive and directly adjacent subgroups of rods and a conductive bridge 42′ that connects two subgroups that are not directly adjacent. It is therefore possible to see that one subgroup 40e is electrically connected to a plurality of subgroups of rods 40c, 40d or to each of the subgroups via an irreversibly modifiable conductive bridge.

The one or more irreversibly modifiable conductive bridges consist of fuse devices that are configured to blow beyond a threshold current value. In their original state, their function is to allow the current to flow between two groups or subgroups that they electrically connect so as to group the various rods together such that they may be activated together. This is particularly useful in the case of an entry-level vehicle, in which fewer lighting and/or signaling functionalities are available. The wiring is in simplified with a single power supply wire feeding all of the rods.

When this light source is to be used for a top-of-the-range vehicle, in which each of the functionalities that are available thanks to the sectioning of the light-emitting rods must be able to be implemented independently of the others, it is sought to recreate the sectioning of the rods by blowing the fuses. The groups or subgroups of rods that are connected by the fuse then become electrically independent of one another and these groups or subgroups must then be activated selectively by means of suitable wiring.

At least one fuse device consists of a zinc and/or gold metal wire, it being understood that this wire has a diameter of about 30 micrometres.

These fuse devices are produced on the first face of the substrate, namely the face from which the light-emitting rods project, while the opposite face of the substrate bears a printed circuit board.

In order to control the activation of the various rods and to allow the shape of the desired lighting and/or signaling beam to be produced, the lighting and/or signaling device includes means for computing a suitable control instruction for turning on the rods, as well as control means that are configured to format and to transmit the control instructions to the various rods to be controlled.

The computing means are configured to generate a control instruction in response to information relating in particular to the environment around the vehicle, and for example relating to traffic conditions and to the presence of a vehicle to avoid dazzling in front of the vehicle, or for example relating to weather conditions and to the presence of rain, which is a trigger for concentrating the projected beam closer to the vehicle.

It is understood that the light source manufactured in the standard way could include a plurality of subgroups that are liable to be activated selectively, i.e. to allow a multifunctional light beam, in a top-of-the-range version, all or some of the subgroups being connected to one another in an entry-level version, so as to simplify the control instructions and the number of electrical wires required for connection.

Provision may be made for a variant embodiment that differs from what has been described above in particular in the arrangement of the irreversibly modifiable conductive bridges. In this variant, the bridges are now arranged on the side of the upper face of the substrate. Although this arrangement may make it more difficult to transform the conductive bridges when needed, due to the presence of the light-emitting rods which complicates the application of the means used to make this modification to the substrate, it is however advantageous for the lower face of the substrate not to be burdened with these conductive bridges. Thus, the soldering of a printed circuit board to the substrate on the side of this lower face is not hindered, such a board being in particular able to be implemented to control the rods in top-of-the-range vehicles.

In another variant, provision may be made for the one or more irreversibly modifiable conductive bridges to consist of antifuse devices that are configured to take effect beyond a threshold voltage value. In this case, in their original state, their function is to block the current between two groups or subgroups that they connect so as to impose a selective activation if such a source is applied as is in a motor vehicle. When it is desired to apply this light source in an entry-level vehicle without selectively activating the rods, it is sought to override the effect of the initial sectioning of the rods by activating the antifuses. By way of example, these antifuses consist of semiconductor components that are made definitively electrically conductive by applying a high voltage that burns out these components. The groups or subgroups of rods that are connected by the fuse then become electrically connected to one another and these groups or subgroups can then only be activated simultaneously, by means of simplified wiring.

A process for manufacturing and a method for using a light source according to the invention will now be described.

Firstly, a standard light source that is liable to be used, before irreversible transformation, for any type of vehicle, i.e. here for any vehicle provided with any lighting and/or signaling functions, is produced.

The standard light source is obtained by stacking various layers on top of one another in order to form the substrate on which the light-emitting rods are grown. When obtaining this substrate by layering, an end layer of the stack with an interconnect mask for electrically interconnecting the rods is formed. This interconnect mask consists of a determined network of electrical connections separating the light-emitting rods projecting from the substrate into various sets, groups or subgroups. At this stage, the rods are distributed in as many sets as necessary to perform each of the lighting and/or signaling functions. By way of example, a boundary line is defined and the rods of a first group arranged on one side of this boundary line are connected separately from the rods of a second group arranged on the other side. In each of these groups, provision is made for the rods to be grouped together into subgroups. In the example illustrated in FIG. 3, provision is thus made for an electrical connection such that the rods of the second group are arranged in five subgroups. In a top-of-the-range version, it is desired to be able to turn on each subgroup separately so as in particular to be able to turn on all of the subgroups when no vehicle is detected on the road and to be able to turn off the rods corresponding to a subgroup on demand when it is desired to avoid dazzling a vehicle. In an entry-level version in which the control module is not configured to manage this type of adaptive beam, it is desired just to turn on all of the sources of the second group simultaneously without having to multiply the connection wires for supplying power to various sets of rods.

One or more irreversibly modifiable connector bridges are then arranged between at least two groups or subgroups of rods. In particular, fuse or antifuse devices may be placed on this interconnect mask, and the choice of either type of device on the standard light source could depend on the number of entry-level or top-of-the-range vehicles envisaged for this type of vehicle.

In the case in which the conductive bridges are arranged on the first face of the substrate, i.e. from which the rods project, the bridges could be modified irreversibly from the opposite face by locally increasing the temperature in the zones directly below the conductive bridges to be modified. The irreversible modification could also, by way of nonexhaustive variant, be made from the front face of the substrate, before depositing the layer for protecting the rods.

A standard light source is thus obtained, the use of which may be envisaged both for an application in a top-of-the-range vehicle, i.e. a vehicle having a plurality of lighting and/or signaling functions, and for an application in an entry-level vehicle.

For an application in a top-of-the-range vehicle, it is desired to confirm the separation of the rods into groups and subgroups provided by the interconnect mask, and actions are taken such that the conductive bridges prevent the electrical connection between the groups or subgroups that they connect. If these conductive bridges consist of antifuse devices, i.e. of devices that, in their original state, do not allow this electrical connection, then they are left in their original state. If, however, these conductive bridges consist of fuse devices, i.e. of devices that, in their original state, allow this electrical connection, then an overcurrent is supplied, with a current passing through the one or more fuses that it is the desired to blow that is higher than a determined threshold value. The fuse devices then assume an irreversible final state, which prevents electrical connection. In both cases, when the conductive bridges are in their desired definitive state, the electrical power supply wires are connected for each of the sets of selectively rods that can be activated selectively.

Starting with the same light source, the steps are taken in reverse if it is desired to apply it to an entry-level vehicle. It is desired to break the separation of the rods into groups and subgroups provided by the interconnect mask, and actions are taken such that the conductive bridges allow the electrical connection between the groups or subgroups that they connect. If these conductive bridges consist of antifuse devices, i.e. of devices that, in their original state, do not allow this electrical connection, then an overcurrent is supplied, with a current passing through the one or more antifuses that it is the desired to burn out that is higher than a determined threshold value. The antifuse devices then assume an irreversible final state, which makes the original semiconductor components conductive and allows the electrical connection. If, however, these conductive bridges consist of fuse devices, i.e. of devices that, in their original state, allow this electrical connection, then they are left in their original state. In both cases, when the conductive bridges are in their desired definitive state, the electrical power supply wires are connected for each of the sets of selectively rods that can be activated selectively, it being understood that the smaller number of these independent assemblies makes it possible to limit the number of power supply wires to be provided.

It is understood that if a vehicle is primarily to be sold as a top-of-the-range version, conductive bridges will be provided in the form of antifuse devices, since no additional step is needed after obtaining the standard light source, while conversely, if a vehicle is primarily to be sold in an entry-level version, conductive bridges will be provided in the form of fuse devices.

If needed, depending on the vehicle range and on the type of conductive bridge originally chosen, the additional step of irreversibly modifying the state of the conductive bridges is carried out by applying a suitable connector to the interconnect mask so as to match at least one of said conductive bridges of the mask with a conductive element of the connector. This conductive element is overheated, which results in the disintegration of the fuse device or the transformation of the antifuse device. This irreversible modification step is carried out prior to connecting a printed circuit board to a lower face of the substrate, facing away from the light-emitting rods.

The preceding description clearly explains how the invention allows the set objectives to be achieved and in particular how it makes it possible to provide a lighting and/or signaling device that is able to use a standard light source regardless of the range of the motor vehicle in which it is desired to apply the device, and hence regardless of the number of lighting and/or signaling functions that it must perform. The standard light source is sufficiently refined in its original arrangement such that later steps for adapting it for a given vehicle range are limited and simplified.

1. Semiconductor light source comprising at least one substrate and a plurality of submillimetre-sized light-emitting rods that extend from a first face of the substrate, said light-emitting rods being arranged in a plurality of groups the selective activation of which allows a plurality of light beams to be produced,
wherein at least two groups of rods are electrically connected to one another by an irreversibly modifiable conductive bridge such that the irreversible modification of this conductive bridge irreversibly modifies the electrical dependence of the two groups on one another.

2. Light source according to claim 1, wherein the light-emitting rods are distributed in a plurality of groups of rods that are arranged in series and the selective activation of which allows a plurality of light beams to be produced, said groups of rods being connected pairwise by an irreversibly modifiable conductive bridge.

3. Light source according to claim 1, wherein the light-emitting rods are distributed in a plurality of groups of rods that are arranged in series and the selective activation of which allows a plurality of light beams to be produced, at least one group of rods being able to be connected to a plurality of groups of rods or to each of the groups of this plurality via an irreversibly modifiable conductive bridge.

4. Light source according to claim 1, wherein a plurality of groups of light-emitting rods that are arranged on one side of a boundary line are connected to one another by irreversibly modifiable conductive bridges, while a set of rods that is distinct from and independent of said groups of rods is arranged on the other side of the boundary line.

5. Light source according to claim 1, wherein the one or more irreversibly modifiable conductive bridges consist of fuse devices that are configured to blow beyond a threshold current value.

6. Light source according to claim 5, wherein at least one fuse device consists of a zinc and/or gold wire.

7. Light source according to claim 6, wherein said wire has a diameter of about 30 micrometres.

8. Light source according to claim 1, wherein the one or more irreversibly modifiable conductive bridges consist of antifuse devices that are configured to take effect beyond a threshold voltage value.

9. Light source according to claim 1, wherein the one or more irreversibly modifiable connector bridges are formed on the first face of the substrate.

10. Light source according to claim 9, wherein the opposite face of the substrate 10 bears a printed circuit board.

11. Lighting and/or signaling device comprising a light source according to claim 1, and further comprising an optic for shaping the rays emitted by the light source for emitting a light beam out of the device.

12. Lighting and/or signaling device according to claim 11, wherein the light source includes a plurality of light-emitting rods that are electrically connected so as to form selectively addressable groups, each of said groups being configured to form a pixel of said light beam, the number and the shape of said pixels potentially changing after the one or more conductive bridges have been irreversibly modified.

13. Process for manufacturing a light source according to claim 1, wherein various layers are stacked to form the substrate on which the light-emitting rods are grown, at least one end layer of the stack consisting of an interconnect mask for electrically interconnecting the rods including one or more reversibly modifiable conductive bridges, and wherein, prior to the operation of connecting a printed circuit board to a face of the substrate facing away from the light-emitting rods, a suitable connector is applied to the interconnect mask so as to match at least one of said conductive bridges of the mask with a conductive element of the connector.

14. Light source according to claim 2, wherein the light-emitting rods are distributed in a plurality of groups of rods that are arranged in series and the selective activation of which allows a plurality of light beams to be produced, at least one group of rods being able to be connected to a plurality of groups of rods or to each of the groups of this plurality via an irreversibly modifiable conductive bridge.

15. Light source according to claim 2, wherein a plurality of groups of light-emitting rods that are arranged on one side of a boundary line are connected to one another by irreversibly modifiable conductive bridges, while a set of rods that is distinct from and independent of said groups of rods is arranged on the other side of the boundary line.

16. Light source according to claim 2,, wherein the one or more irreversibly modifiable conductive bridges consist of fuse devices that are configured to blow beyond a threshold current value.

17. Light source according to claim 16, wherein at least one fuse device consists of a zinc and/or gold wire.

18. Light source according to claim 17, wherein said wire has a diameter of about 30 micrometres.

19. Light source according to claim 2, wherein the one or more irreversibly modifiable conductive bridges consist of antifuse devices that are configured to take effect beyond a threshold voltage value.

20. Light source according to claim 2, wherein the one or more irreversibly modifiable connector bridges are formed on the first face of the substrate.
